(19) United States
(12) Patent Application Publication
(10) Pub. No.: US 2005/0018506 A1
(43) Pub. Date: Jan. 27, 2005

(54) Sense amp equilibration device

(76) Inventor: William Kenneth Waller, Eagle, ID (US)

Correspondence Address: William K. Waller, 2262 N. Greenview Ct, Eagle, ID, 83616, US

(21) Appl. No.: 10/625,751

(22) Filed: Jul. 23, 2003

(51) Int. Cl. G11C 7/00

(52) U.S. Cl. 365/203

(57) ABSTRACT

A dynamic random access memory sense amp equilibration and biasing circuit with reduced transistor count allowing an interstitial layout, thus substantially reducing circuit area requirements.

### CROSS-REFERENCE to RELATED APPLICATIONS

Not applicable.

### STATEMENT REGARDING FEDERALLY SPONSORED RESEARCH and DEVELOPMENT

Not applicable

### BACKGROUND OF THE INVENTION

1. Field of the Invention

This invention relates to monolithic dynamic random access memory array circuitry and, more particularly, to techniques for sense amp equilibration.

2. Description of the Prior Art

Monolithic dynamic random access memory (DRAM) devices are well known. Within a DRAM, data is transported between sense amp and array on a complementary-logic bitline. After a read or refresh cycle, the complementary-logic bitline pairs are equilibrated to match each other, and biased to a predetermined voltage so they can be properly read by their sense amp in a future cycle.

During a read or refresh cycle, a selected data cell is connected to its bitline, raising or lowering the bitline from its bias voltage. Its sense amp then senses the small voltage difference between the new bitline level and its bias level, and amplifies that difference to a full logic one or logic zero level. In this way, the infinitesimal charge of a tiny memory cell is captured and presented to the rest of the chip and consequently to the outside world. The charge of the data cell is also refreshed by the amplified voltage level on the bitline. The bitline equilibration and bias circuitry is commonly considered to be part of the sense amp circuitry.

It is also known that circuit area, sometimes called “real estate”, is at a premium. The smaller a device can be made, the faster it is likely to be, and more economical to manufacture. Consequently, semiconductor engineers and mask designers all over the world perpetually strive to reduce circuit size in order to stay cost competitive.

In a DRAM device, the memory array by far takes the most real estate. Second to the memory array in size are the sense amps and related circuitry. Even a small area reduction for a single sense amp is multiplied across all the sense amps, and chip size consequently can be significantly reduced, thus improving cost competitiveness.

Blodgett, in patent U.S. Pat. No. 6,466,499 B1, herein incorporated by reference, shows typical DRAM technology, and is state-of-the-art, indicated by its very recent issue date of Oct. 15, 2002. Conventional three-transistor sense amp equilibrate and bias circuits are shown as elements 50a and 50b in FIGS. 1, 2, 4, 5A, 5B, and 5C.

In Blodgett, equilibrate transistor 54 is gated by equilibrate signal EQa to short complementary-logic bitlines D0 and D0* together, thus equilibrating them. EQa also gates bias transistors 56 and 58, so that bias transistor 56 shorts bitline D0 to node Veq, and so that bias transistor 58 shorts bitline D0* to node Veq. D0 and D0* are thus biased to the voltage on node Veq.

For clarity and ease of comparison, in the present specification, prior art is represented in the present application in FIGS. 1 and 2. FIG. 1 is a typical prior art circuit schematic, and FIG. 2 is that schematic represented in a layout. Because of the common and extensive use in the industry of symmetry and reflected layouts for elegant design, four bitline pairs with their relevant associated devices are shown in FIG. 2.

In FIGS. 1 and 2, EQ is the equilibrate signal gating equilibrate transistor Q1, and biasing transistors Q2 and Q3, BL and BLn are the complementary-logic bitlines, and the bias voltage node is Vbias. When EQ is activated, equilibrate transistor Q1 shorts BL and BLn together (thus equilibrating them), and biasing transistor Q2 shorts bitline BL to biasing node Vbias, and biasing transistor Q3 shorts bitline BLn to biasing node Vbias, (thus biasing the bitlines).

Typical prior art as illustrated in FIG. 1 is deficient, in that with equilibrate transistor Q1 in the circuit, biasing transistors Q2 and Q3 are redundant with each other, wasting real estate.

Further, as shown in FIG. 2, the substrate contact for n-channels, referred to as PPLUG, must be placed outside of the QL devices, thus increasing layout size. Also, the Vbias contact needs to be placed outside of the source/drain of n-channel Q3′ and Q3″, further increasing the layout size, as represented by L1.

Zagar, in patent US RE35,825, herein incorporated by reference, is a prior art attempt to avoid problems due to row-to-column shorts, and to reduce transistor count. There is no equilibrate transistor, as that function is taken over by biasing transistors QnA/QnB being activated simultaneously. As shown in Zagar FIG. 4, four complementary-logic bitline pairs D1/D1* through D4/D4* share a common current-limiting device QL. Each bitline pair has biasing transistors Q1A/Q1B through Q4A/Q4B, connected in the conventional way and gated by equilibrate node EQ. Instead of one current limiting device per bitline pair, Zagar reduces area requirements by using one current limiting device QL per four bitline pairs, which is gated permanently on, and biases the bitline pairs at the voltage on node DVC.

Performance in Zagar is compromised because both BLs are shorted (equilibrated) through two series n-channel transistors (Q1A and Q1B, for example), instead of through a single transistor, thus doubling equilibrate time. Two series transistors of one width will have half of the drive of a single transistor of the same width, hence slower equilibration performance. The biasing speed is not as critical as the equilibrate speed. Zagar thus reduces transistor count, but at the expense of slowing equilibration time.

### SUMMARY OBJECTS and ADVANTAGES of the INVENTION

Disclosed herein is a new DRAM complementary-logic bitline equilibration and biasing circuit, which has the distinct advantage of being implemented using less real estate than prior art, thus lowering the manufacturing cost of the DRAM.

Specifically, this is accomplished by eliminating one of the bias transistors per bitline pair. Said transistor has not been hitherto recognized as redundant.

This allows a smaller circuit layout which significantly reduces the area of sense amps and related circuitry, while preserving identical control requirements and performance.

### DRAWING FIGURES

List of Drawing Figures:

FIG. 1 shows a schematic of typical prior art bitline pair equilibrate and bias circuitry.

FIG. 2 shows a typical layout four bitline pairs using the circuit of FIG. 1.

FIG. 3 shows a schematic of the inventive bitline pair equilibrate and bias circuitry.

FIG. 4 shows a layout of four bitline pairs using the inventive circuitry of FIG. 3.

### LIST OF REFERENCE NUMERALS

BL is a logic-true side of a complementary-logic bitline pair.
BLn is a logic-inverse side of a complementary-logic bitline pair.
EQ is an equilibrate node/contact which carries an equilibrate signal and gates Q1, Q2, and Q3.
PPLUG is substrate contact for n-channels.
Q1 is an equilibrate transistor.
Q2 is a biasing transistor.
Q3 is a second biasing transistor.
QL is a current limiting device connecting biasing transistor(s) to Vbias.
Vbias is a biasing node/contact, holding a bias voltage between logic one and logic zero.
L1 is a representative length of a layout of the prior art circuit.
L2 is a representative length of a layout of the inventive circuit.

### DESCRIPTION and OPERATION of the PREFERRED EMBODIMENT

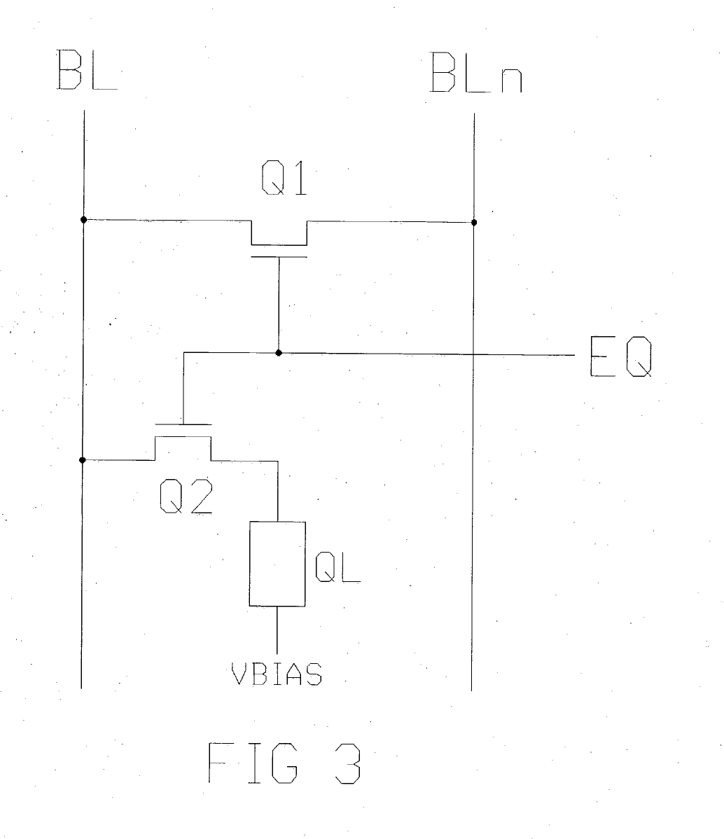

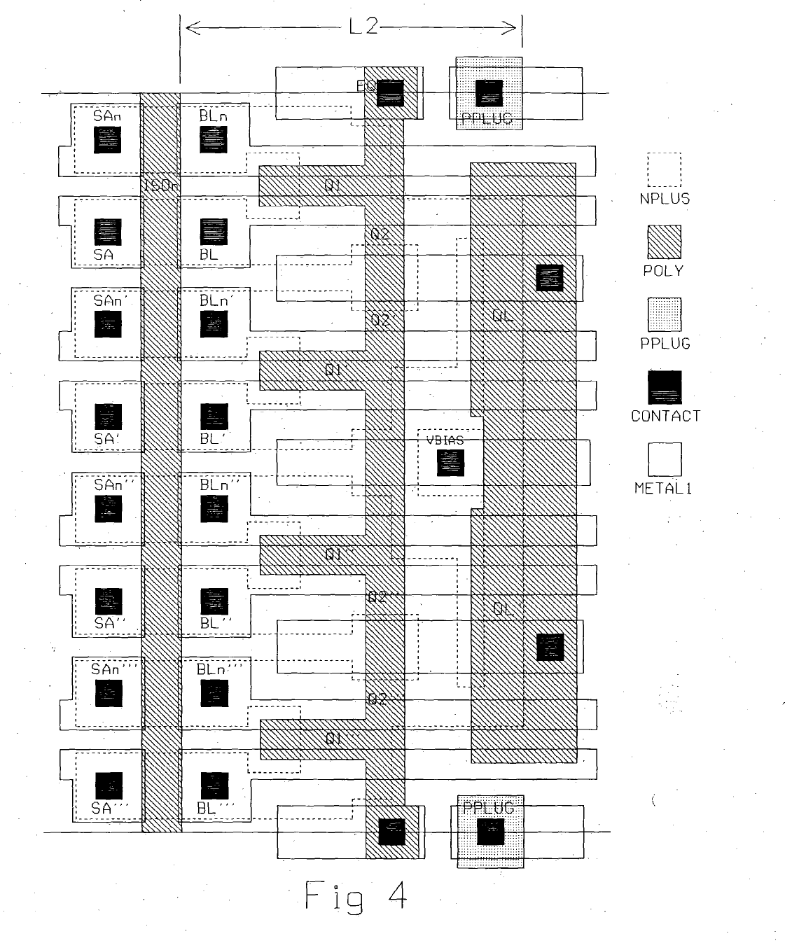

Please refer to FIGS. 3 and 4. FIG. 3 is a circuit schematic of the inventive circuit, and FIG. 4 is that schematic represented in a layout. Because of the common and extensive use in the industry of symmetry and reflected layouts for elegant design, four bitline pairs with their relevant associated devices are shown in FIG. 4.

BL and BLn are bitlines in a typical complementary-logic bitline pair, within a typical DRAM chip. Transistors Q1 and Q2 and current limiting device QL function as bitline pair equilibrate and bias circuitry, the function of which is well-known in the art.

Equilibrate transistor Q1 is gated by equilibrate node EQ, and is also connected to BL and BLn, so that when Q1 is activated by EQ, BL and BLn are shorted together through Q1. Biasing transistor Q2 is gated by equilibrate node EQ, and is also connected to BL and to the drain terminal of current limiting device QL, so that when Q2 is activated by EQ, BL is shorted to QL. The source terminal of QL is connected to bias node Vbias.

QL is a resistive device well known in the art, such as a long-L transistor, and its function is to limit current flow, so that if a bitline has a fault, Vbias is not depleted of charge and is still able to bias healthy bitlines.

Equilibrate signal EQ gates equilibrate transistor Q1, and biasing transistor Q2. When activated, equilibrate transistor Q1 shorts BL and BLn together. And when activated, biasing transistor Q2 shorts BL to biasing node Vbias through current limiting device QL. Because Q1 and Q2 are activated simultaneously, BLn is shorted to BL, which is shorted to Vbias (through current limiting device QL), thus simultaneously equilibrating and biasing both BL and BLn.

In all respects, the inventive is controlled the same as in prior art.

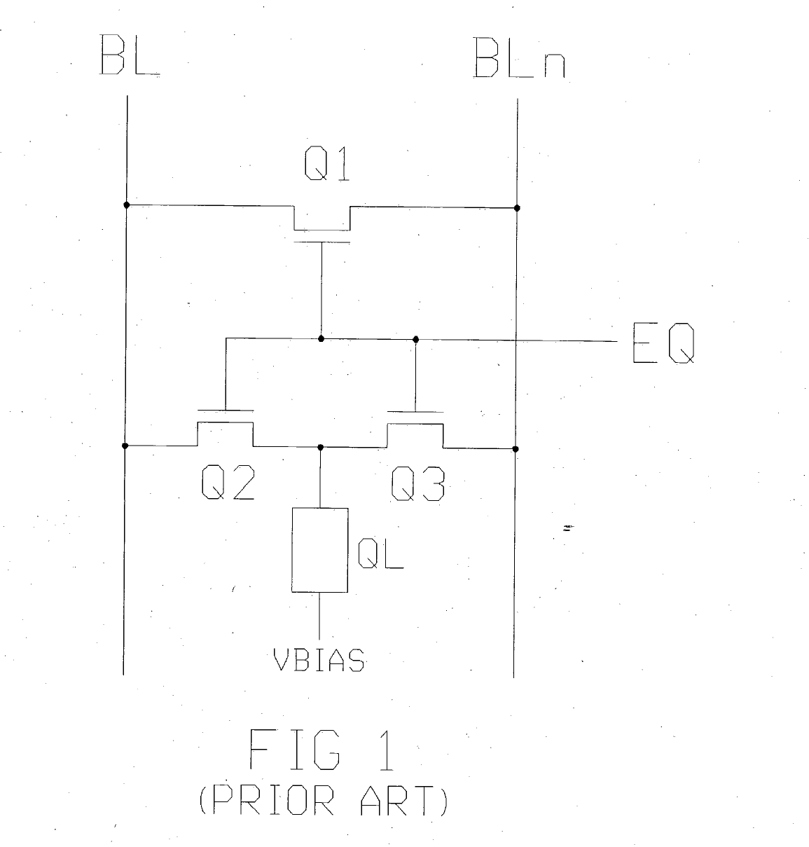

The difference between this circuit and prior art is that prior art uses two bias transistors, Q2 and Q3 (as shown in FIG. 1), and the inventive circuit uses only Q2 (as shown in FIG. 3), requiring less circuit area. Those familiar with the art had not hitherto recognized that Q2 and Q3 are redundant with each other. Equilibration speed through Q1 is identical to prior art as shown in FIG. 1, only now with reduced transistor count, and also better than Zagar.

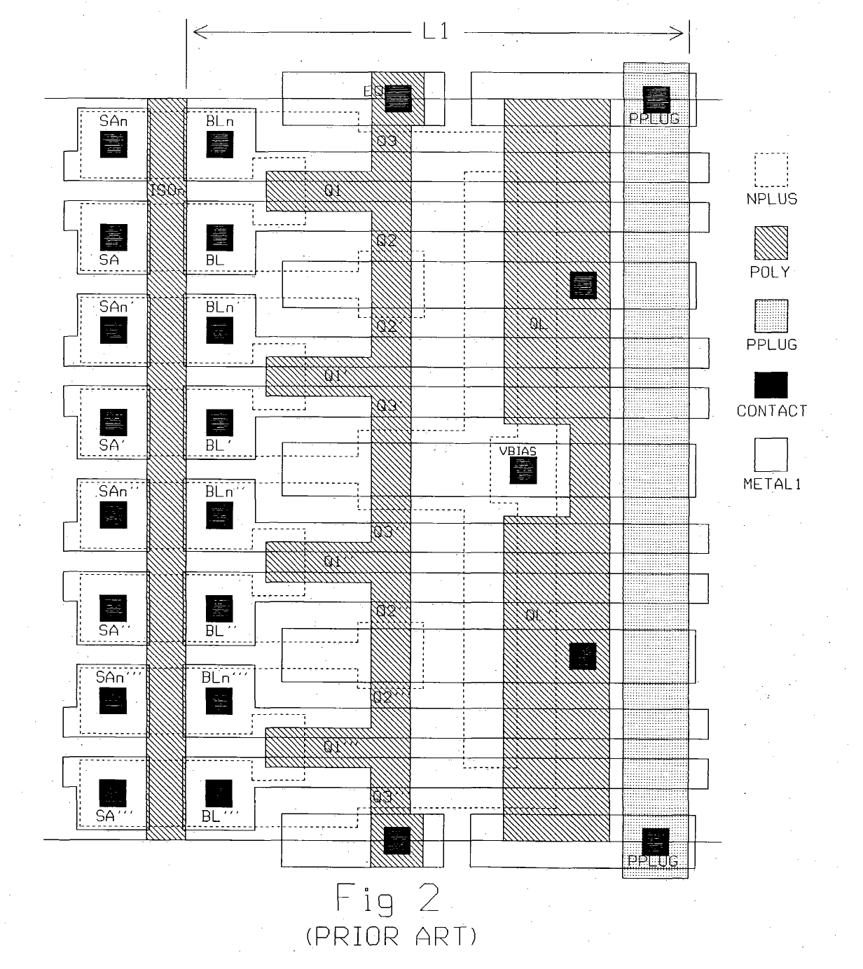

Referring to inventive layout in FIG. 4 in comparison to typical prior art in FIG. 2, it can be seen that the inventive elimination of Q3 allows the shifting of bias node Vbias, into the space vacated by the source terminal of former Q3′ and Q3″ of prior art, in an interstitial and more compact fashion. PPLUG can now also be placed in the space vacated by the drain terminal of former QL and QL′ of prior art, next to the QL devices instead of outside of them, as indicated by comparing FIGS. 2 and 4.

The prior art layout of FIG. 2 has a representative length of L1. The inventive layout of FIG. 4 has a representative length of L2. Because of the interstitial layout of Vbias between Q2′ and Q2″, and the n-channel substrate contact being next to the QL devices, the inventive circuit results in a more compact design, as indicated by L2 being significantly smaller than L1, thus having reduced manufacturing cost.

For purposes of this application, in regard to layout, ‘next to’ refers to an orientation wherein an element can be placed between duplicate equilibrating circuitry blocks, allowing interstitial location between repeating blocks. This is illustrated in FIG. 4 of the invention, where Vbias is ‘next to’ Q1′, which allows for interstitial location of Vbias between repeating blocks, as evidenced by Vbias being interstitially located between Q1′ and Q1″. This is in contrast to ‘outside of’ which refers to an orientation which cannot be interstitially oriented between repeating blocks, such as shown in FIG. 2 (prior art), where Vbias is located ‘outside of’ devices Q3′ and Q3″.

This is also illustrated in FIG. 2, where prior art PPLUG is located ‘outside of’ the QL devices, as compared to inventive FIG. 4, where PPLUG is located ‘next to’ the QL devices.

### CONCLUSION RAMIFICATIONS, and SCOPE

While there is shown and described the present preferred embodiment of the invention, it is to be distinctly understood that this invention is not limited thereto but may be variously embodied to practice within the scope of the following claims.

For example, bias transistor Q2 can be connected to BL rather than BLn. The equilibrate circuitry can be used in other sense amps not connected to BLs but to a data path, for example, so by ‘bitline pair’, a data path is also circumscribed. The inventive circuitry is also valid, independent of location of isolation devices between the array and sense amps: that is, the inventive circuitry is valid on either side of array isolation devices. Adding a two-terminal n-channel device in place of the three-terminal n-channel device Q3 to balance BL and BLn more closely will still be within the scope of the invention. Also, current limiting device QL may or may not be required, depending on overall circuit design of the chip. So when the Vbias node is indicated connected to a biasing voltage circuit, a current limiting device may or may not be a part of that biasing voltage circuit. In this case, PPLUG can then be located ‘next to’ Vbias, rather than QL, resulting in the same inventive intent of reducing circuit length.

Clearly, other layouts may be conceived which express the reduced real estate requirements of the inventive circuitry. Such layouts are expressions of the inventive circuitry and are therefore within the scope of this invention. Also, though the above description discloses many details, these details should not be understood to limit the current invention. Obvious variations such as a minor change in logic design, addition of passive devices, or a modified scheme for writing and reading data, while making use of the structures, functions, or methods of the current invention, would fall within the scope of the patent rights claimed by the inventor. Therefore the scope of the invention should be limited only by the appended claims and their legal equivalents.

1. In a dynamic random access memory device, having a complementary-logic bitline pair having true and inverted bitlines:
equilibrating means, connected to the bitline pair; and
biasing means, connected to only one of the bitlines;
wherein when said equilibrating and biasing means are activated together, the bitline pair is thus equilibrated and biased.

2. The device of claim 1, wherein:
said equilibrating means comprises a first transistor, connected to the bitline pair, such that when activated, the bitlines are shorted together;
said biasing means comprises a second transistor, connected to only one of the bitlines and connected to a biasing node, such that when activated, the one of said bitlines is shorted to said biasing node;
such that when said first and second transistors are activated together, said bitline pair is equilibrated and biased.

3. The device of claim 2, wherein said biasing node is located next to said second transistor.

4. The device of claim 2, wherein said biasing node is connected to a current-limiting device, and wherein an n-channel substrate contact can be located next to said current-limiting device without widening circuit area.

5. The device of claim 2, wherein an n-channel contact can be located next to said biasing node, without widening circuit area.

6. In a dynamic random access memory device, having a biasing node, and first and second complementary-logic bitline pairs each having a true and an inverted bitline:
first equilibrating means, able to short the bitlines of the first bitline pair together;
second equilibrating means, able to short the bitlines of the second bitline pair together;
first biasing means, able to short only one of the bitlines of the first bitline pair to the biasing node;
second biasing means, able to short only one of the bitlines of the second bitline pair to the biasing node;
wherein the biasing node is interstitially located between said first and second biasing means.

7. The device of claim 6, wherein:
said first equilibrating means comprises a first transistor, connected to the first bitline pair, such that when said first transistor is activated, the first bitline pair is shorted together;
said second equilibrating means comprises a second transistor, connected to the second bitline pair, such that when said second transistor is activated, the second bitline pair is shorted together;
said first biasing means comprises a third transistor, connected to only one of the bitlines in the first bitline pair and connected to a biasing node, such that when said third transistor is activated, the one of said bitlines of the first bitline pair is shorted to said biasing node;
said second biasing means comprises a fourth transistor, connected to only one of the bitlines in the second bitline pair and connected to said biasing node, such that when said fourth transistor is activated, the one of said bitlines of the second bitline pair is shorted to said biasing node;
wherein said first, second, third, and fourth transistors are activated together, thus equilibrating and biasing the bitline pair.

8. The device of claim 7, wherein said biasing node is connected to a current-limiting device, and wherein an n-channel substrate contact can be located next to said current-limiting device without widening circuit area.

9. The device of claim 7, wherein an n-channel contact can be located next to said biasing node, without widening circuit area.

10. In a dynamic random access memory device, having:
an equilibrate node;
a biasing node;
a complementary-logic bitline pair having true and inverted bitlines;
a first transistor, connected to said bitline pair and gated by said equilibrate node such that when said equilibrate node is activated, said bitline pair is shorted together and thus equilibrated;
a second transistor, connected to said true bitline and to said biasing node, and gated by said equilibrate node, such that when said equilibrate node is activated, said true bitline is shorted to said biasing node, thus biasing said true bitline;
a third transistor, connected to said inverted bitline and to said biasing node, and gated by said equilibrate node, such that when said equilibrate node is activated, said inverted bitline is shorted to said biasing node, thus biasing said inverted bitline;
the improvement comprising:
conversion of one of said second and third transistors from a three-terminal device to a two-terminal device, allowing said biasing node to be located next to remaining unconverted of said second and third transistors, without widening circuit area.

11. The device of claim 10, wherein said biasing node is connected to a current-limiting device, and wherein an n-channel substrate contact can be located next to said current-limiting device without widening circuit area.

12. The device of claim 10, wherein an n-channel contact can be located next to said biasing node, without widening circuit area.

13. In a dynamic random access memory device, having:
an equilibrate node;
a biasing node;
a complementary-logic bitline pair having true and inverted bitlines;
a first transistor, connected to said bitline pair and gated by said equilibrate node such that when said equilibrate node is activated, said bitline pair is shorted together and thus equilibrated;
a second transistor, connected to said true bitline and to said biasing node, and gated by said equilibrate node, such that when said equilibrate node is activated, said true bitline is shorted to said biasing node, thus biasing said true bitline,
a third transistor, connected to said inverted bitline and to said biasing node, and gated by said equilibrate node, such that when said equilibrate node is activated, said inverted bitline is shorted to said biasing node, thus biasing said inverted bitline;
the improvement comprising:
elimination of one of said second and third transistors, allowing said biasing node to be located next to remaining of said second and third transistors, without widening circuit area.

14. The device of claim 13, wherein said biasing node is connected to a current-limiting device, and wherein an n-channel substrate contact can be located next to said current-limiting device without widening circuit area.

15. The device of claim 13, wherein an n-channel contact can be located next to said biasing node, without widening circuit area.
